(19) United States
(12) Patent Application Publication
(10) Pub. No.: US 2006/0245485 A1
(43) Pub. Date: Nov. 2, 2006

(54) Continuous-time equalizer

(75) Inventors: Aaron K. Martin, El Dorado Hills, CA (US); Pavan Kumar V. Hanumolu, Corvallis, OR (US); Randy Mooney, Beaverton, OR (US)

Correspondence Address: FLESHNER-KIM, LLP;INTEL CORPORATION, P.O. BOX 221200, CHANTILLY, VA, 20153-1200, US

(73) Assignee: Intel Corporation

(21) Appl. No.: 11/116,401

(22) Filed: Apr. 28, 2005

(51) Int. Cl. H03H 7/30

(52) U.S. Cl. 375/229

(57) ABSTRACT

A continuous-time equalizer includes a first transconductance circuit to set a gain of an amplified signal in a link and a second transconductance circuit to set a zero frequency in a transfer function of the equalizer. The zero frequency controls a frequency range of the signal amplified in the link based on the gain set by the first transconductance circuit.

### FIELD

This invention generally relates in one or more of its embodiments to signal processing circuits for suppressing interference and/or other forms of noise.

### BACKGROUND OF THE INVENTION

Limited bandwidth is a major limitation in high-speed digital systems because it causes signal losses that degrade performance. The losses are principally caused by skin effects, or frequency-dependent attenuation, that occur along the signal line. This attenuation produces distortion in the form of inter-symbol interference (ISI) which negatively affects voltage and timing margins in the transmitted signal. These effects become more pronounced at the copper interconnects of the line, where reflections, dielectric loss, and other degrading influences are introduced.

Various techniques have been developed to compensate for these losses including pre-emphasis at the transmitter and discrete-time equalization at the receiver. Pre-emphasis compensates for loss by pre-processing the signal before transmission, for example, by generating over-drive signals to boost higher frequencies. Discrete-time equalization involves sampling and then processing the signal at the receiver. Both approaches have proven unsatisfactory, e.g., pre-emphasis is bounded by limited transmitter power and discrete-time equalization requires signals to be transmitted at precise high-speeds and requires additional hardware (e.g., clocking and sampling circuits) at the receiver which increases complexity and power consumption.

### BRIEF DESCRIPTION OF THE DRAWINGS

FIG. 1 is a diagram showing an active, tunable continuous-time equalization circuit in accordance with one embodiment of the present invention.

FIG. 2 is a diagram showing one type of linear amplifier which may be included in the equalization circuit of FIG. 1.

FIG. 3 is a graph showing a frequency response produced by the linear amplifier of FIG. 2 under a sample set of conditions.

FIGS. 4(a) and 4(b) are graphs showing eye diagrams produced in server channels with and without a receiver equalization circuit having a frequency response as shown in FIG. 3.

FIG. 5 is a diagram showing an active, tunable continuous-time equalization circuit in accordance with another embodiment of the present invention.

FIG. 6 is a graph showing a frequency response of the equalization circuit of FIG. 5 produced under a sample set of conditions.

FIG. 7A is a diagram showing functional blocks included in a method for performing equalization in a signal line in accordance with one embodiment of the present invention, and FIGS. 7B and 7C show functional blocks which may correspond to blocks B110 and B120 respectively in FIG. 7A.

FIG. 8 is a diagram showing one way amplification jitter may form in a source synchronous clocking system over a chip-to-chip link.

FIGS. 9(a) and 9(b) are graphs showing performance results which either of the equalization circuits of FIGS. 2 and 5 is capable of generating when applied to a source synchronous clocking system, under a sample set of conditions.

FIGS. 10(a) and 10(b) are graphs showing additional performance results comparing data rate versus jitter amplification.

FIG. 11 is a diagram of a system which may include or be coupled to any one of the equalization circuit embodiments of the present invention.

### DETAILED DESCRIPTION OF THE EMBODIMENTS

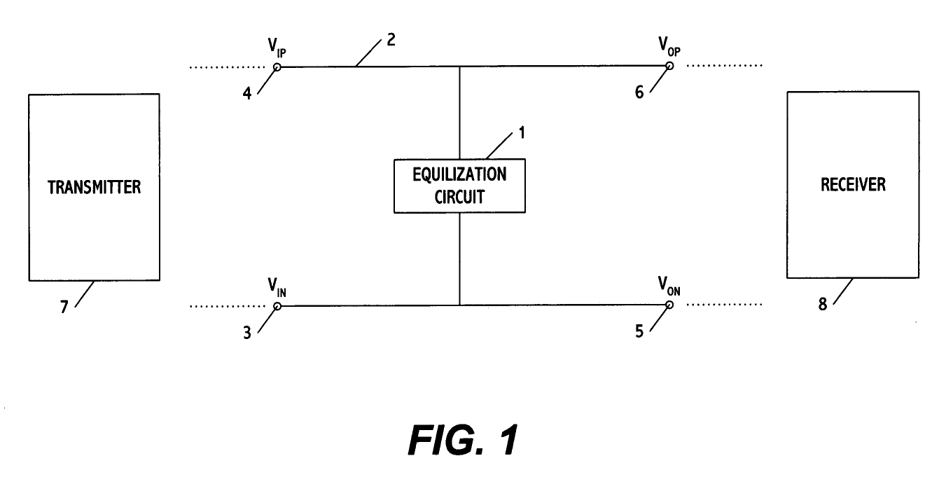

FIG. 1 shows an active, tunable continuous-time equalization circuit 1 in accordance with one embodiment of the present invention. The equalization circuit may be coupled to a receiving end of a link 2 that demonstrates transmission line characteristics. For example, the link may be a lossy interconnect between two chips such as a server channel, a bus, or a copper trace on a printed circuit board, as well as other types of signal interfaces including but not limited to coaxial cables and twisted-pair cables just to name a few.

The equalization circuit operates as a linear amplifier having differential inputs and outputs. Terminals 3 and 4 are inverting and non-inverting input terminals which receive differential signals Vᵢₙ and Vᵢₚ from a transmitting end 7 of the signal line. Terminals 5 and 6 are inverting and non-inverting terminals which output differential signals Vₒₙ and Vₒₚ from the amplifier, for example, to a signal line receiver 8. (The subscripts “n” and “p” stand for negative and positive, or equivalently inverting and non-inverting, respectively). As a continuous-time circuit, the equalizer may not sample the transmitted signal before it reaches the receiver. Instead, the signal may be directly conveyed from the link to the equalizer, thereby avoiding the use of clocking/sampling circuits which tend to increase power and complexity in other architectures.

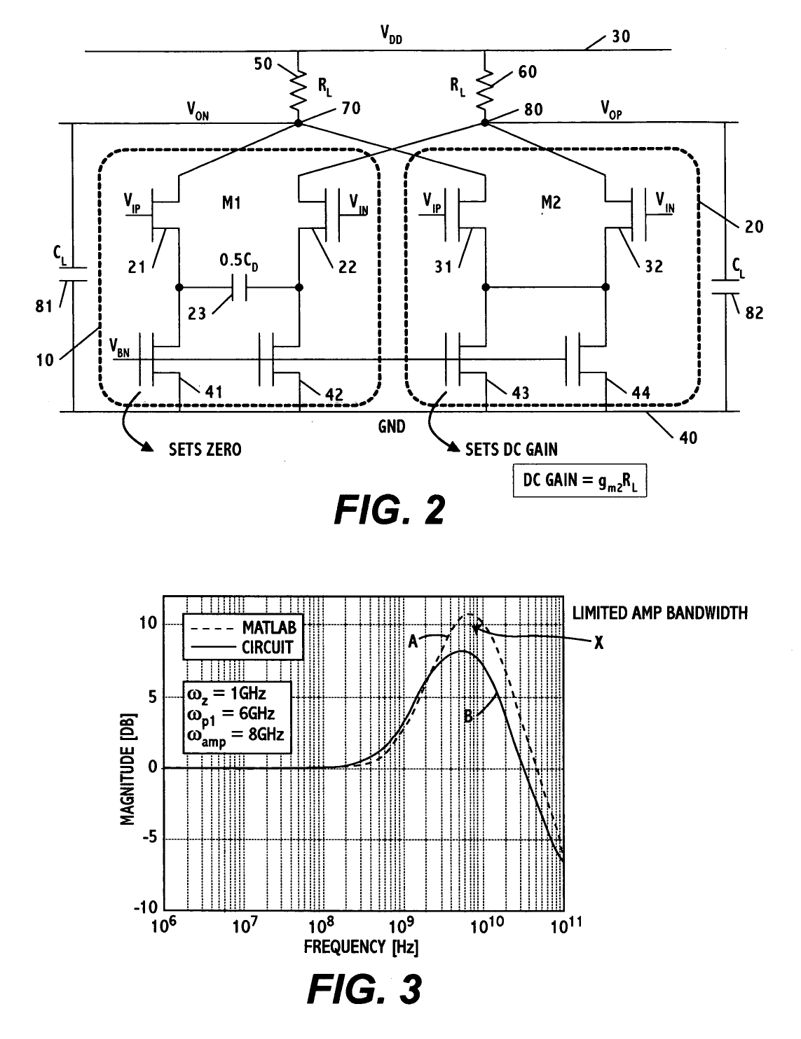

Referring to FIG. 2, the linear amplifier is formed from two transconductance circuits 10 and 20 coupled between a voltage supply rail (V_{DD}) 30 and a reference line 40, e.g., ground. The first circuit 10 includes a differential pair of transistors 21 and 22 and a capacitor 23 coupled between their drains. The capacitor may have a value equal to 0.5 C_{D}, where C_{D} represents the capacitance between the drains of the transistors. The value of0.5 is used to simplify the equations discussed below so that these equations have no numbers, just variables. The 0.5 value may be omitted or replaced by another value in other embodiments.

The second circuit 20 includes a differential pair of transistors 31 and 32 having a common source or drain. The gates of transistors 22 and 32 are controlled by differential signal Vᵢₙ received from the inverting input terminal of the signal line, and the gates of transistors 21 and 31 are controlled by differential signal Vᵢₚ received from the non-inverting terminal of the signal line.

The transconductance circuits are connected to the supply rail through resistors 50 and 60. In accordance with this embodiment, the sources of transistors 21 and 31 are coupled to the supply rail through resistor 50 and the sources of transistors 22 and 32 are coupled to the supply rail through resistor 60. Resistors 50 and 60 may have the same resistance value R_{L}, as this common-load proves advantageous for some high-speed applications. In alternative embodiments, resistors 50 and 60 may have different values. The output terminals of the linear amplifier may be coupled to nodes 70 and 80, e.g., Vₒₙ is derived from node 70 and Vₒₚ is derived from node 80.

Both transconductance circuits optionally include circuits for biasing the operating voltages of the transistors. These circuits may be formed from transistors 41-44 having gates commonly coupled to a bias voltage V_{bn} generated from a control circuit (not shown). The bias voltage may be set to satisfy the requirements of a signal line application. The linear amplifier may also include a pair of capacitors 81 and 82 (C_{L}) located between differential output terminals Vₒₙ and Vₒₚ and the reference rail. These capacitors are load capacitors of a succeeding stage which may be matched in terms of their capacitance values. In many applications, C_{L} should be minimized in order to extend the bandwidth of the equalizer to a maximum.

In operation, transconductance circuit 20 determines the DC gain of the amplifier output and transconductance element M1 determines the frequency range of the signals amplified by the gain. The DC gain may be determined as follows:
DC Gain=gₘ₂·R_{L} (1)
where gₘ₂ represents the transconductance of differential pair of transistors 31 and 32 and R_{L} represents the common-load resistance. From Equation (1), it is clear that the gain of the amplifier may be adjusted either by selecting the value of common-load resistor R_{L} or by scaling the transconductance gₘ₂ of circuit 20. By modifying one or both of these parameters, a wide-tuning range for the equalization gain may be attained. The gain may be set, for example, based on channel, process, and/or signal-to-noise targets for a particular application.

The frequency range of the signals amplified by the gain is determined by introducing a zero in the transfer function of the equalization circuit. In transconductance circuit 10, creating this zero (or peaking effect) causes the gain of the equalizer to increase at a particular frequency, which, for example, may correspond to the frequency of the transmitted signals or some other frequency relating to the link. The zero frequency ω_{Z} is given by the following equation:

$${ω}_{z} = \frac{f}{f + 1} {ω}_{p} \qquad ( 2 )$$

While only one zero is created in the transfer function of this embodiment, other embodiments may introduce additional zeros, for example, to meet the requirements of a particular application.

From Equation (2) it is clear that the zero frequency is a function of ωₚ and f, where ωₚ represents the frequency where a pole occurs in the frequency response and f represents a ratio of the transconductances of circuits 10 and 20. The same capacitor, C_{D}, which sets the zero in the transfer function also sets the pole. These parameters may be defined as follows:

$$\begin{matrix}{ω}_{p} = \frac{{g}_{m 1}}{{C}_{D}} & ( 3 ) \\ f = \frac{{g}_{m 2}}{{g}_{m 1}} & ( 4 )\end{matrix}$$

where gₘ₁ is the transconductance of circuit 10, gₘ₂ is the transconductance of circuit 20 and C_{D} is the value of the capacitor coupled between the drains of transistors 21 and 22 in circuit 10.

Equations (2)-(4) therefore make clear that the zero created in the transfer function of the equalization circuit is based on the value of capacitor C_{D}, and that adjusting the value of this capacitor will tune the frequency response of and thus the equalization performed by the linear amplifier throughout a predetermined operational range. This range may be determined by one or more parameters of the amplifier. The bandwidth of the chip-to-chip interconnect that the amplifier is attempting to equalize is one such parameter, but other parameters may also be used.

Moreover, the dependence of the transfer function on this ratio results from a summation of the signals from circuits 10 and 20 into nodes 70 and 80 of the common-load resistance R_{L}. The value of resistance R_{L} taken in combination with the line capacitance C_{L} for each of the circuits, therefore, determines ωₚ_{_{—}}ₐₘₚ:

$${ω}_{p\_amp} = \frac{1}{{R}_{L} {C}_{L}} \qquad ( 5 )$$

From Equation (5), it is clear that adjusting one or both of R_{L} and C_{L} will effect a proportional change in ωₚ_{_{—}}ₐₘₚ to thereby tune the equalization circuit.

Transconductance circuits 10 and 20, thus, form a dual-path structure coupled to a common-load resistance. This structure equalizes frequency-dependent attenuation, or loss, in the signal line, thereby producing a flatter overall frequency response compared with other methods. As a result, signal distortion produced by inter-symbol interference at chip-to-chip interconnects is significantly reduced within the limited bandwidth of the signal link. Moreover, the dual-path structure does not suffer from limited transmitter power constraints and requires no clocks, two drawbacks which limit the performance of other transconductance circuits.

FIG. 3 shows the frequency response produced by the linear amplifier of FIG. 2 under a sample set of conditions, e.g., where R_{L}=160 Ω, C_{L}=0.1 pF, C_{D}=0.2 pF, transconductance gₘ₁=25 mA/V, transconductance gₘ₂=6 mA/V, V_{DD}=1.8V, and power=10 mW. Under these conditions, a zero frequency (ω_{z}) was created at 1 GHz, a first pole frequency (ωₚ₁) at 6 GHz, and a frequency (ωₐₘₚ) of 8 GHz. The graph further shows, by Curve A, that the amplifier can provide more than 10 dB of equalization (i.e., ISI suppression), which may prove especially beneficial for purposes of equalizing a channel used in a server application, e.g., a 20-inch signal line of FR4 insulation forming a chip-to-chip link between two connectors. Curve B corresponds to a Spice simulation performed at the transistor level. This curve has less bandwidth that Curve A because it includes transistor parasitic capacitance. Arrow X indicates that Curve B has less peaking compared to the frequency response of Curve A, which thereby produces the smaller bandwidth.

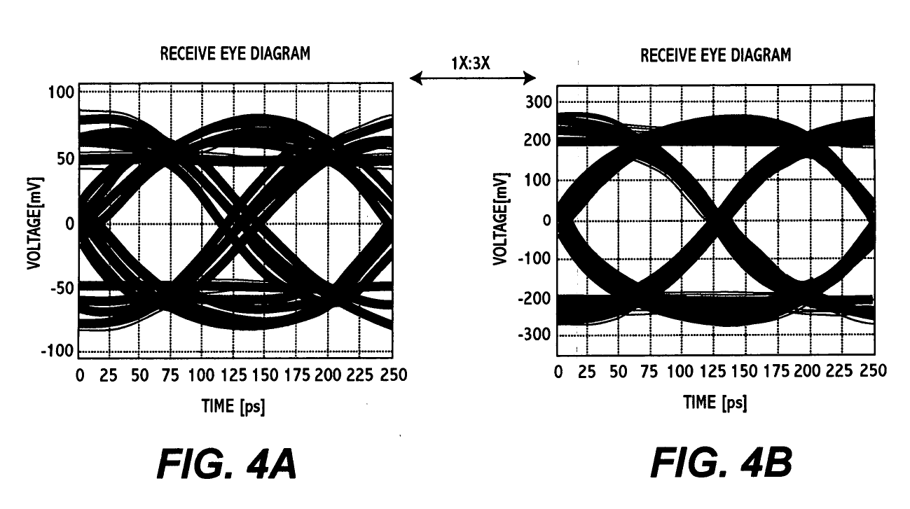

FIG. 4(a) shows an eye diagram generated by a server channel carrying signals at a data rate of 8 Gbps and with 5-tap pre-emphasis implemented at the transmitter, and FIG. 4(b) shows the eye diagram generated by a server channel carrying signals at the same data rate with 1-tap pre-emphasis and receiver equalization performed by the linear amplifier of FIG. 3. A comparison of these graphs shows that FIG. 4(b) has a wider, taller, and more well-defined eye compared with FIG. 4(a) which results from the ISI suppression provided by the linear amplifier. FIG. 4(b) also has less spreading in the time dimension (x axis), which indicates improved timing uncertainty and improved performance.

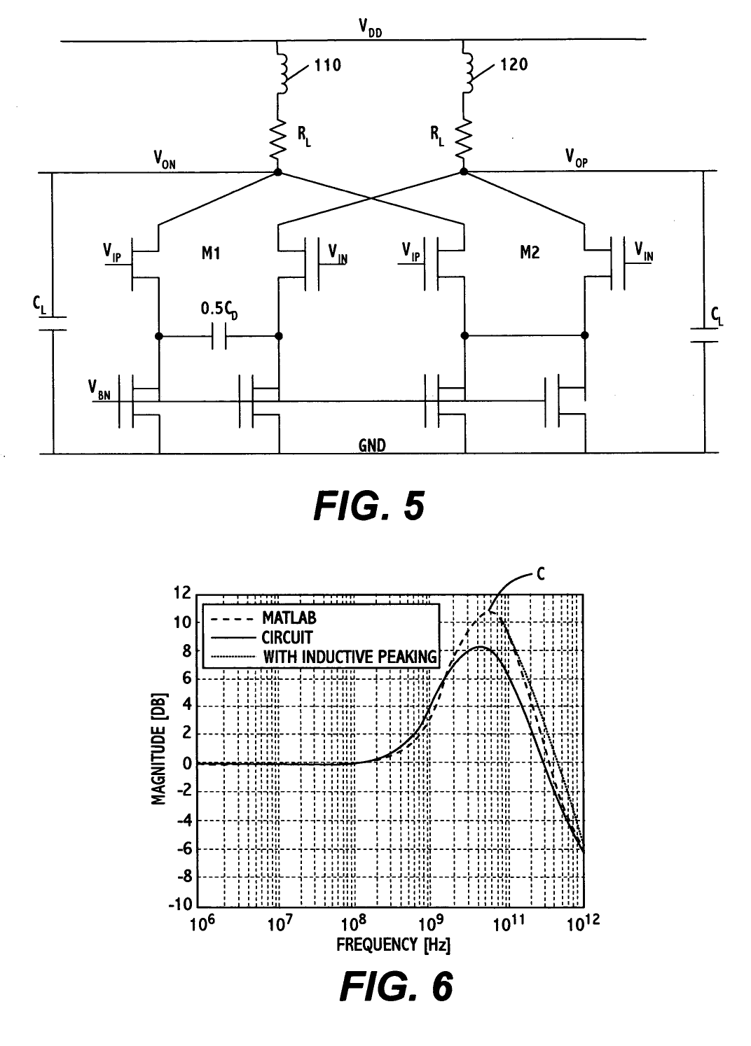

FIG. 5 shows an active, tunable continuous-time equalization circuit 100 in accordance with another embodiment of the present invention. This circuit is the same as the linear amplifier of FIG. 2 except that inductors 110 and 120 are coupled between the load resistors R_{L} and the supply rail. The inductors cause the amplifier to perform an inductive/shunt peaking function which adds even more peaking in the frequency response compared with the circuit of FIG. 2. This, in turn, increases bandwidth of the channel when the circuit is placed in series with the channel, and the increased bandwidth generates improved performance of chip-to-chip data and clock channels.

FIG. 6 is a graph showing a frequency response of the equalization circuit of FIG. 5 produced under a sample set of conditions, e.g., where R_{L}=160 Ω, C_{L}=0.1 pF, L=2 nH, C_{D}=0.2 pF, transconductance gₘ₁=25 mA/V, transconductance gₘ₂=6 mA/V, V_{DD}=1.8V, and power=10 mW. Under these conditions, a zero frequency (ωₐₘₚ) was created at approximately 1 GHz, a first pole frequency (ωₚ₁) at 6 GHz, and a frequency (ωₐₘₚ) of 8 GHz. The graph further shows, by Curve C, that the amplifier can provide more than 10 dB of equalization (i.e., ISI suppression), which may prove especially beneficial for purposes of equalizing a channel used in a server application, e.g., a 20-inch signal line of FR4 insulation forming a chip-to-chip link between two connectors. This amplifier may also better overcome parasitics compared with the FIG. 2 circuit, at least for some applications.

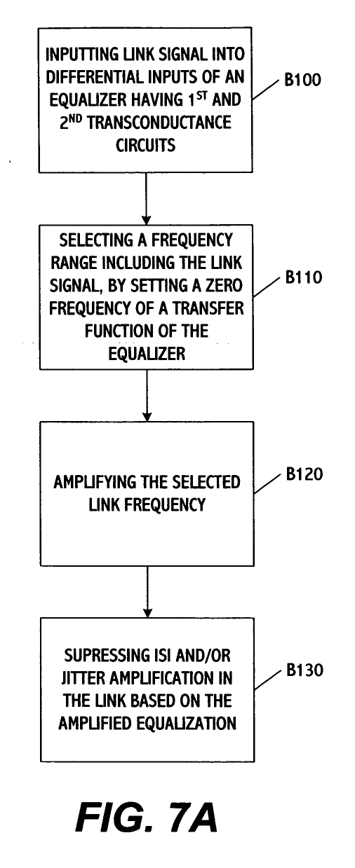

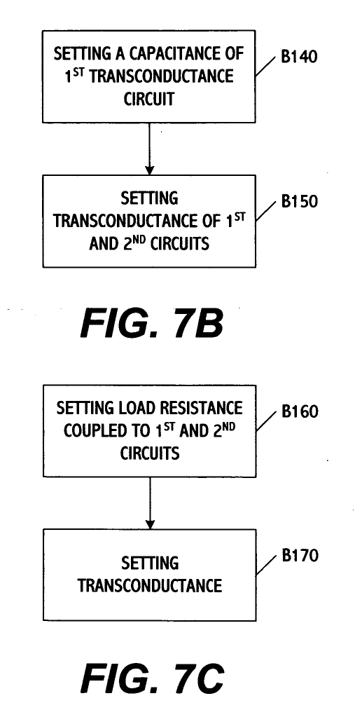

FIG. 7A shows functional blocks included in a method for performing equalization in a signal line in accordance with one embodiment of the present invention. Initially, a link signal is connected to differential inputs of an equalizer coupled to a receiving end or any other position along the link. (B100). The equalizer may be either of the circuits shown FIGS. 2 and 5 applied to suppress ISI or other forms of noise, including jitter amplification as described in greater detail below. The link may be a chip-to-chip interconnect or any of the other types of links previously described.

Once the signal is received, the equalizer selects a frequency range including the link signal (e.g., data signal or clock channel signal), by setting a zero frequency of a transfer function of the equalizer. (B110). This may be performed based on the foregoing equations, e.g., setting a capacitance of C_{D} and transconductance values of the first and second transconductance circuits forming the equalizer. (See B140 and B150 in FIG. 7B).

Once the frequency range including the link signal has been selected, the signal is amplified (B120), for example, by setting the load resistance coupled to the first and second transconductance circuits (B160 in FIG. 7C). This amplification may also be based on transconductance values of one or both of the transconductance circuits in the equalizer. (B 170 in FIG. 7C). Based on this frequency selection and amplification, a signal emerges from the equalizer which suppresses inter-symbol interference or jitter amplification or some other parameters of interest. (B130). The parameter affected depends on the zero frequency selected, e.g., the zero frequency selected determines which frequencies in the link will be amplified. Accordingly, the zero frequency may be selected to amplify a data or clock channel signal while simultaneously suppressing jitter amplfication and ISI noise.

Besides reducing inter-symbol interference, the equalization circuit may be implemented to mitigate jitter amplification in source synchronous clocking systems. In these systems, which are found in IO buses of many computer platforms, a separate channel transmits a clock signal over the link. The receiver then uses this signal to automatically synchronize the transmitted data.

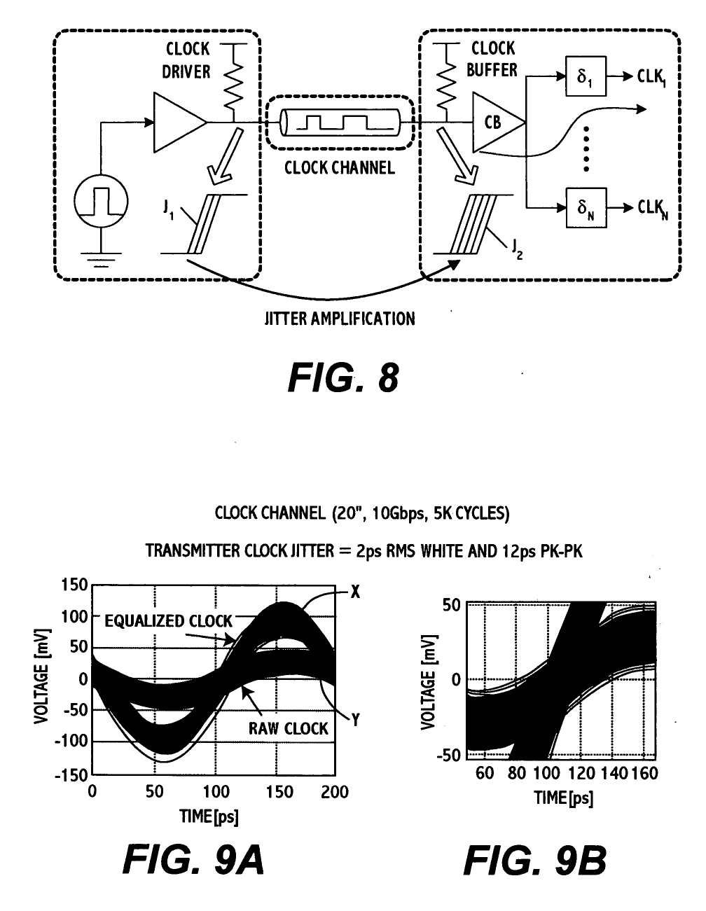

As data rates and frequency-dependent attenuation (channel loss) increase, the clock signal may experience significant attenuation. To offset this effect, the clock may be amplified at the receiver using limiting-amplifiers. However, these amplifiers amplify jitter along with the clock signal, thereby degrading link performance. This situation is depicted in FIG. 8, which shows that jitter (J₁) on the transmitting side of the link is enhanced (J₂) by a limiting amplifier in a clock buffer (CB) at the receiving end of the link.

Because jitter amplification is predominantly caused by limited channel bandwidth, a continuous-time equalizer in accordance with any one of the embodiments of the present invention may be implemented to boost high-frequency loss in the clock channel, to thereby amplify the clock signal while simultaneously reducing jitter amplification. This may be accomplished by tuning one of the linear amplifiers in FIGS. 2 and 5 to have gain peaking at a high frequency range which includes the clock signal.

More specifically, the equalizer flattens the overall frequency response of the channel so that clock jitter going into the channel will not be amplified after passing through the equalizer. The jitter amplification effect is a result of the limited bandwidth of the interconnect. By extending the bandwidth of the interconnect using the equalizer, the amplification of jitter is reduced, if not completely removed. (Jitter passed through a low-pass filter is amplified at the output when the clock frequency is above the bandwidth of the filter. The same occurs when a clock is passed through a lossy channel. This equalizer makes the channel less lossy, or in other words, extends the bandwidth.)

The linear amplifier may be tuned to perform this selective amplification function by setting the zero in its transfer function so that zero frequency ω_{z} corresponds to the clock signal frequency. This, in turn, may be accomplished by setting capacitor C_{D} to an appropriate value, thereby creating gain peaking at high frequencies which include the clock signal frequency in the clock channel. An equalizer tuned in this manner may be placed at any location along the link where the channel begins to attenuate the clock, not only at the receiving end.

FIGS. 9(a) and 9(b) shows an example of the performance that may be obtained when the linear equalizer is placed in a channel twenty inches long that carries a clock signal at 10 Gbps with 5K cycles. As shown in FIG. 9(a), the amplitude of the equalized clock signal (X) is greater than the raw clock signal (Y). Concurrently, the transmitter clock jitter in this channel was reduced to 2 ps rms white and 12 ps peak-to-peak.

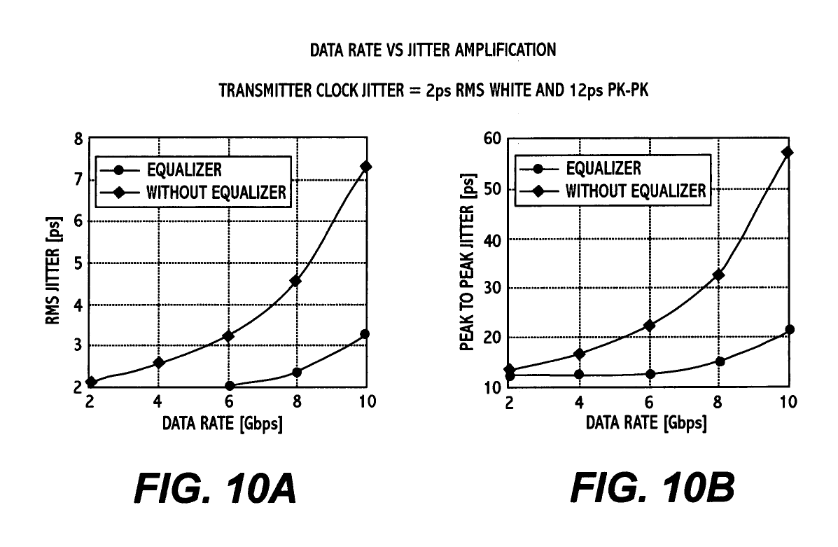

FIGS. 10(a) and 10(b) shows an example of the performance that may be obtained when the equalizer is placed in a data channel. When implemented in this manner, capacitor C_{D} may be adjusted to create a zero in the transfer function which corresponds to the data signal frequency, while simultaneously suppressing jitter amplification. In FIG. 10(a), the equalizer reduced the jitter-to-data rate ratio measured in RMS jitter (ps) versus data rate in Gbps. In FIG. 10(b), the equalizer reduced this ratio measured in peak-to-peak jitter (ps) versus data rate in Gbps. For both graphs, the transmitter clock jitter equaled 2 ps rms white and 12 peak-to-peak.

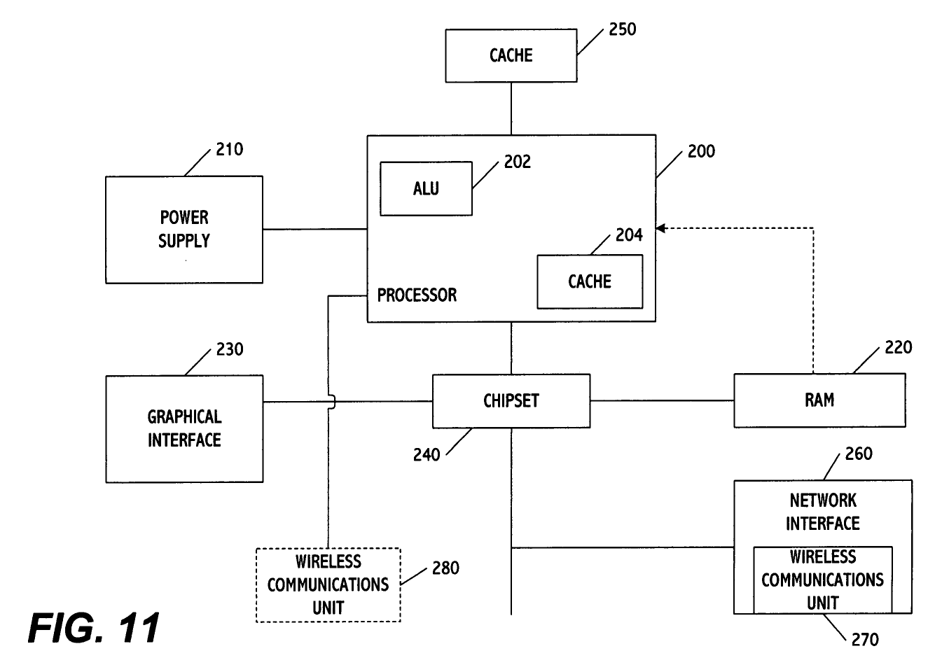

FIG. 11 shows a system which includes a processor 200, a power supply 210, and a memory 220 which, for example, may be a random-access memory. The processor includes an arithmetic logic unit 202 and an internal cache 204. The system may also include a graphical interface 230, a chipset 240, a cache 250, a network interface 260, and a wireless communications unit 270, which may be incorporated within the network interface. Alternatively, or additionally, the communications unit 280 may be coupled to the processor, and a direct connection may exist between memory 220 and the processor as well.

In this system, a receiver coupled to a continuous-time equalizer in accordance with any of the foregoing embodiments may be included in any of the blocks except the power supply, for suppressing inter-symbol interference and/or jitter amplification in signals received over a signal line, such as a chip-to-chip link, server channel, clock channel, or any other signal transmission line or interface. While the equalizer is shown as residing on the chip, the equalizer may alternatively be positioned off-chip in advance of the receiver.

The processor may be a microprocessor or any other type of processor, and may be included on a chip die with all or any combination of the remaining features, or one or more of the remaining features may be electrically coupled to the microprocessor die through known connections and interfaces. Also, the connections that are shown are merely illustrative, as other connections between or among the elements depicted may exist depending, for example, on chip platform, functionality, or application requirements.

Any reference in this specification to an “embodiment” means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Furthermore, for ease of understanding, certain functional blocks may have been delineated as separate blocks; however, these separately delineated blocks should not necessarily be construed as being in the order in which they are discussed or otherwise presented herein. For example, some blocks may be able to be performed in an alternative ordering, simultaneously, etc.

Although the present invention has been described herein with reference to a number of illustrative embodiments, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

We claim:

1. A continuous-time equalizer, comprising:
a first transconductance circuit to set a gain of an amplified signal in a link; and
a second transconductance circuit to set a zero frequency in a transfer function of the equalizer, wherein the zero frequency controls a frequency range of the signal amplified in the link based on the gain set by the first transconductance circuit.

2. The equalizer of claim 1, wherein the gain and frequency range equalize frequency-dependent attenuation in the link to reduce inter-symbol interference.

3. The equalizer of claim 1, further comprising:
a resistive circuit coupled to the first and second transconductance circuits,
wherein a resistance of the resistive circuit controls the gain of the amplified signals.

4. The equalizer of claim 3, wherein the resistive circuit includes a common load resistor coupled between the first and second transconductive elements and a supply potential.

5. The equalizer of claim 1, wherein the first transconductance element includes a differential pair of transistors having a transconductance which controls the gain of the amplified signals.

6. The equalizer of claim 5, wherein said pair of transistors have a common source.

7. The equalizer of claim 1, wherein the zero frequency of the transfer function of the equalizer is based on a pole frequency of the transfer function.

8. The equalizer of claim 1, wherein the zero frequency of the transfer function of the equalizer is based on a transconductance value of the second transconductance circuit.

9. The equalizer of claim 1, wherein the zero frequency of the transfer function of the equalizer is based on a ratio of transconductance values of the first and second transconductance circuits.

10. The equalizer of claim 1, wherein the second transconductance element includes:
a differential pair of differential transistors; and
a capacitor coupled between the differential transistors, wherein the zero frequency of the transfer function of the equalizer is based on capacitance value of the capacitor.

11. The equalizer of claim 1, wherein the first transconductance circuit includes first and second transistors having a common terminal and the second transconductance circuit includes third and fourth transistors coupled through a capacitor, and wherein gates of the first and third transistors receive a first signal and gates of the second and fourth transistors receive a second signal, with the first and second signals forming a differential signal carried through the link.

12. The equalizer of claim 11, further comprising:
a load resistance coupled between the first, second, third, and fourth transistors and a supply potential, wherein the load resistance determines the gain set by the first transconductance circuit and the capacitor determines the frequency range set by the second transconductance circuit.

13. The equalizer of claim 12, further comprising:
a first node coupled between the load resistance and the first and third transistors; and
a second node coupled between the load resistance and the second and fourth transistors, the first and second nodes outputting the amplified signals as a differential output signal of the equalizer.

14. The equalizer of claim 13, wherein the gain and frequency range equalize frequency-dependent attenuation in the link to reduce inter-symbol interference in the differential output signal.

15. The equalizer of claim 1, wherein the link is a chip-to-chip interconnect.

16. A continuous-time equalizer, comprising:
a first transconductance circuit to set a gain of the equalizer; and
a second transconductance circuit to set a zero frequency in a transfer function of the equalizer, wherein the zero frequency is tuned to selectively amplify a clock channel signal in a source synchronous clocking system based on the gain set by the first transconductance circuit, while simultaneously suppressing jitter amplification in the channel.

17. The equalizer of claim 16, wherein the first transconductance circuit includes first and second transistors having a common terminal and the second transconductance circuit includes third and fourth transistors coupled through a capacitor, and wherein gates of the first and third transistors receive a first signal and gates of the second and fourth transistors receive a second signal, with the first and second signals corresponding to the clock channel signal in differential form.

18. The equalizer of claim 17, further comprising:
a load resistance coupled between the first, second, third, and fourth transistors and a supply potential, wherein the load resistance determines the gain set by the first transconductance circuit and the capacitor tunes the second transconductance circuit to select a frequency of the clock channel signal for amplification based on the gain of the first transconductance circuit.

19. The equalizer of claim 18, further comprising:
a first node coupled between the load resistance and the first and third transistors; and
a second node coupled between the load resistance and the second and fourth transistors, the first and second nodes outputting the differential clock channel signal amplified by the gain.

20. A method for equalizing signals in a transmission line, comprising:
setting a gain of a first transconductance circuit to amplify a signal in the line; and
setting at least one parameter of a second transconductance circuit to control a zero frequency in an equalization transfer function, the zero frequency being controlled by said at least one parameter to select a frequency of the signal in the line for amplification based on the gain set in the first transconductance circuit.

21. The method of claim 20, wherein the gain and frequency are set to equalize frequency-dependent attenuation in the line to reduce inter-symbol interference.

22. The method of claim 20, wherein the first transconductance circuit includes first and second transistors having a common terminal and the second transconductance circuit includes third and fourth transistors coupled through a capacitor, and wherein gates of the first and third transistors receive a first signal and gates of the second and fourth transistors receive a second signal, with the first and second signals forming the amplified signal in differential form.

23. The method of claim 22, further comprising:
setting a value of a load resistance coupled between the first, second, third, and fourth transistors and a supply potential, wherein the load resistance value determines the gain set by the first transconductance circuit and the capacitor tunes the second transconductance circuit to the frequency of the signal in the line.

24. The method of claim 20, wherein the signal in the line is a clock channel signal in a source synchronous clocking system, and wherein said at least one parameter sets the zero frequency to selectively amplify the clock channel signal based on the gain set by the first transconductance circuit, while simultaneously suppressing jitter amplification in the channel.

25. The method of claim 20, wherein said at least one parameter is a value of a capacitor coupling a differential pair of transistors in the first transconductance circuit.

26. A system, comprising:
a first circuit; and
a continuous-time equalizer coupled to the first circuit and including:
(a) a first transconductance circuit to set a gain of a signal received from a link,
(b) a second transconductance circuit to set a zero frequency in a transfer function of the equalizer, wherein the zero frequency controls a frequency range of the signals amplified in the link based on the gain set by the first transconductance circuit.

27. The system of claim 26, wherein the first circuit is selected from the group consisting of a processor, a power supply, a memory, a chipset, a graphical interface, a network interface, wireless communications unit, and a cache.

28. The system of claim 26, wherein the gain and frequency range equalize frequency-dependent attenuation in the link to reduce inter-symbol interference.

29. The system of claim 26, wherein the signal is a clock channel signal in a source synchronous clocking system, and wherein the clock channel signal is selectively amplified based on the gain and frequency range while jitter amplification in the line is simultaneously suppressed.

30. The system of claim 20, wherein the zero frequency of the transfer function of the equalizer is set based on a value of a capacitor coupling a differential pair of transistors in the first transconductance circuit.
